(19) United States
(12) Patent Application Publication
(10) Pub. No.: US 2002/0073368 A1
(43) Pub. Date: Jun. 13, 2002

(54) Pre-stored digital word generator

(76) Inventors: Angus Chen, Hsin-Chu (TW); Ray Chen, Hsinchu (TW); Glen Chen, Hsinchu (TW)

Correspondence Address: H.C. Lin, 8 Schindler Court, Silver Spring, MD, 20903, US

(21) Appl. No.: 09/730,998

(22) Filed: Dec. 7, 2000

(51) Int. Cl. G11C 8/00

(52) U.S. Cl. 714/724

(57) ABSTRACT

A digital word is generated by storing the timing of the leading edge and trailing edge in a digital memory. The memory is addressed from a counter. The timing of the output of the memory is compared with a reference leading edge timing and a reference trailing edge timing in separate digital comparators. The coincidence of the timing of the stored timing in the memory and the reference timing sets and resets a flip-flop to generate a digital word.

### BRACKGROUND OF THE INVENTION

1. Field of the Invention

This invention relates to digital word generator, particularly to multiple word generator for a particular test point.

2. Brief Description of the Related Art

FIG. 1 shows a prior art digital word generator. A rising edge counter 102 to used to preset a flip-flop 12 to output a digital “1”. Another counter 104 is used to clear the flip-flop 12 to output a digital “0”.

If the digital word contains many pulses, each pulse requires a setup like FIG. 1, and large number of setups will be required. Also, if multiple number m of digital words need to be applied to a particular test point, then m number of such digital word generators must be connected in parallel. Such a set up is bulky and expensive.

### SUMMARY OF THE INVENTION

An object of this invention is to generate multiple pulse digital words. Another object of this invention is to apply multiple digital words to the same test point in testing a digital equipment. Still another object of this invention is to reduce to cost of testing a digital equipment. A further object of this invention is to make easy to program the digital word generator.

These objects are achieved by storing the test sequence in a digital memory. The memory output feeds a sequence of digital signals to a first register. The content of the first register is compared with a reference digital word. When the digital word in the register coincides with the reference digital word, the comparator outputs a “1” signal to preset a flip-flop. The memory also feeds another sequence of digital signals to a second register. The content of the second register is compared with another reference digital word. When the digital word in the second register coincides with the second reference digital word, the comparator outputs a “clear” signal to clear the flip-flop. The same memory can generate a large number of digital words.

In another embodiment, the memory may furnish different words to different channels. The memory stores a series of marked timing pulses to the registers. Each channel has its own comparators with different timing references and its own flip-flop. The flip-flops are preset and cleared at different timings. In this case the first register and the second register may be combined.

### BRIEF DESCRIPTION OF THE DRAWINGS

FIG. 1 shows a prior art single digital word generator.

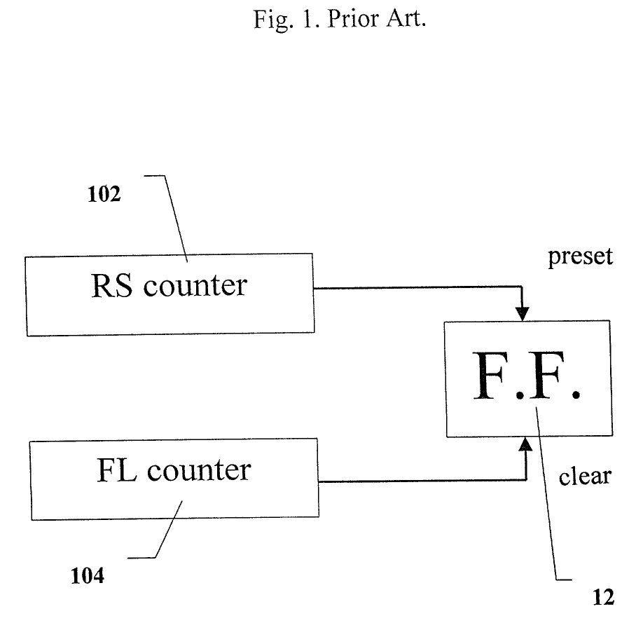

FIG. 2 shows the block diagram of a digital word generator based on the present invention.

FIG. 3a shows the block diagram of a three-channel word generator;

FIG. 3b shows the timing diagram of the three-channel word generator.

### DETAILED DESCRIPTION OF THE INVENTION

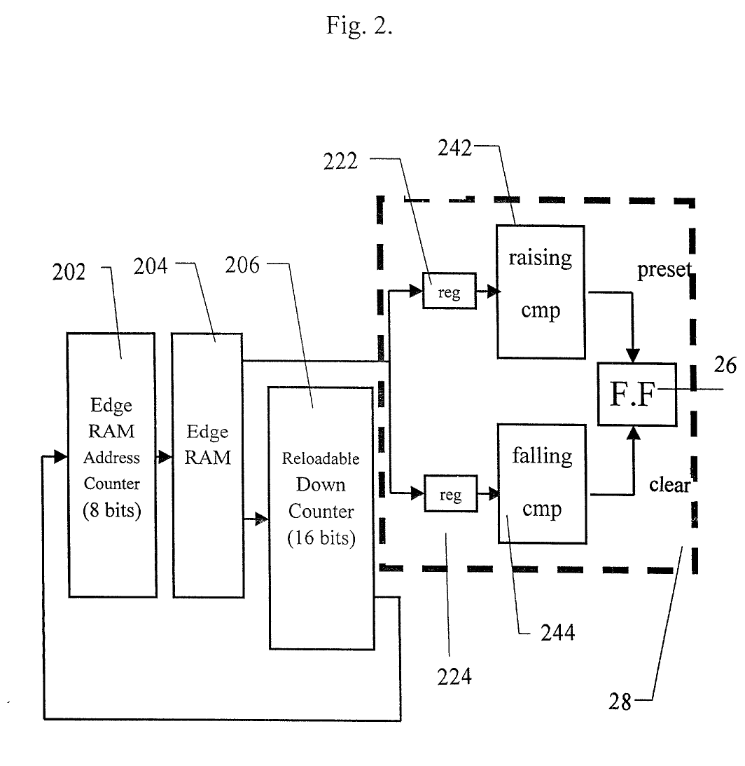

FIG. 2 shows the block diagram of the present invention. The edge random access memory (RAM) 204 stores the rise time (in terms of pulse number) at which the word generator should output a high (“1”) signal and the fall time at which the word generator should output a low (“0”) signal. When the appropriate rise timing arrives, the memory sends a rising edge digital word to the register 222. The word in the register 222 is compared with a reference word in a digital comparator. If the registered word agrees with the reference word, the digital comparator presets the flip-flop 26 to yield a “1” output. The “1” output of the flip-flop stays high until the flip-flop 26 is cleared. When the appropriate fall timing arrives, the memory sends another falling edge word to the register 224. The falling edge word is compared with a falling edge reference signal in a second comparator 244. If the word in the register 224 coincide with the falling edge reference word, the flip-flop 244 output s “0” signal to clear the flip-flop 26.

The timing of the Edge RAM 204 is controlled by the Edge Address Counter 202. This Counter 202 outputs a digital (eight bit) address (D0, D2, . . . D7) as it counts. When the counter counts to the time when the output pulse of the flip-flop should rise, the memory 204 is addressed to feed a rise time word to the register 222. Since this word in the register coincides with the rise time reference word, the rise time comparator presets the flip-flop 26 to yield a “1” output. When the counter 202 counts to the time when the output pulse of the flip-flop should fall, the memory 204 is addressed to feed fall time word to the register 244. Since this fall time word coincides with the fall time reference word, the fall time comparator clears the flip-flop to yield a “0” output.

The Edge RAM also feeds Reloadable Down Counter (16 bits) to recycle the word generator. When the Down Counter completes a cycle of counts, the Down counter starts over again. The generated digital becomes periodic.

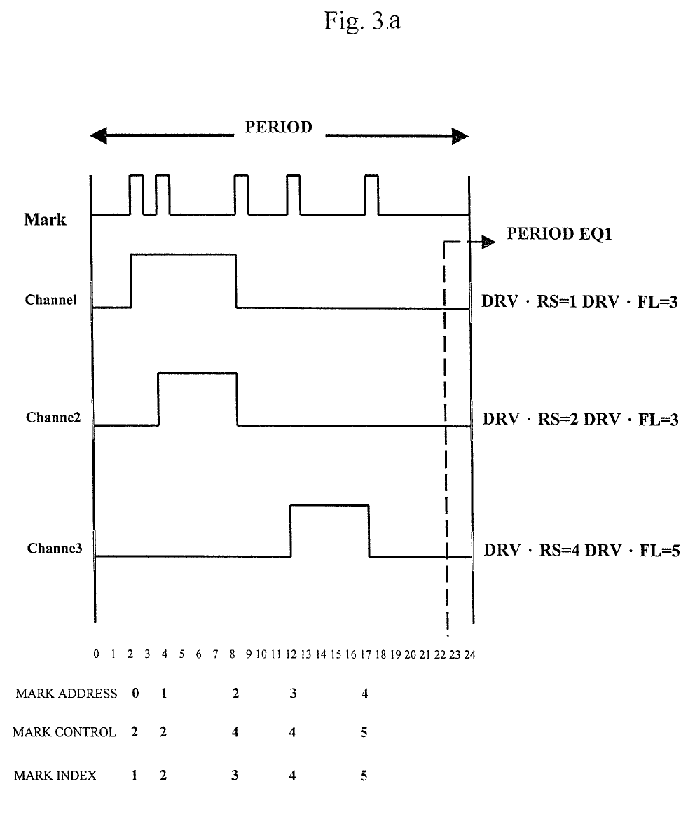

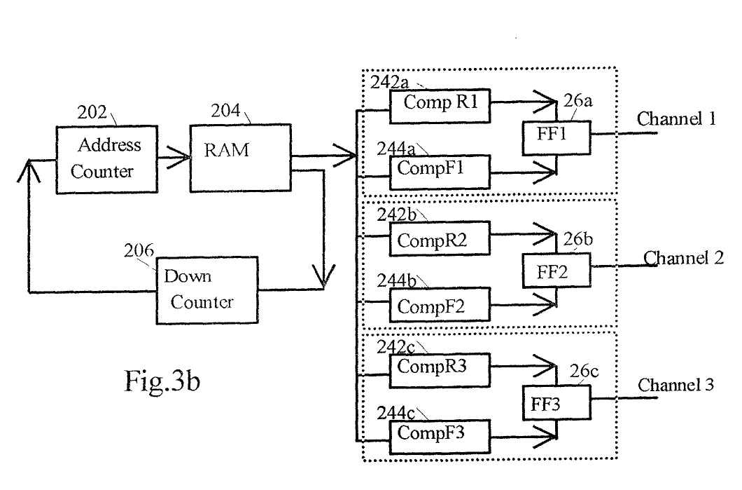

The same memory can be used to supply different digital words to different test points. FIG. 3a shows the timing diagram of an example for three channels (Channel 1, Channel 2, Channel 3) to supply three different words to three different test points. FIG. 3b shows the block diagram for implementing the timing diagram. The desired timing for the different channels are shown in FIG. 3a. In this example, the total time has 24 divisions. The Mark signal has the first mark pulse at rise time at time T2 and fall time at time T3; the second mark pulse has rise time at time T4 and fall time T5; the third mark pulse has rise time at time T8 and fall time at time T9; the fourth mark pulse has rise time at time T12 and fall time at time T13; the fifth mark pulse has rise time at time T18 and fall time at time T19. The timing for channel 1, channel 2 and channel 3 are derived from the Mark timing pulses in the top row. When the address counter 202 counts to the mark times (i.e. T2, T4, T8, T12, T17), a logic “1” is outputted from the memory. These mark pulses are compared differently for the three channels as shown in the block diagram in FIG. 3b. For each channel, there are separate rise time comparators 242a, 242b, 242c; fall time comparators 244a. 244b, 244c and flip-flops 26a, 26b, 26c, respectively. Each comparator has its unique reference timing and is compared with the mark timings from the memory. For instance, channel 1 has a rise time reference pulse at T2 and a fall time reference pulse at T8; channel 2 has a rise time reference at T4 and fall time reference at T8; channel 3 has a rise time reference at T12 and a fall time reference at T17. The coincidence of the rise time mark pulse from the memory with the rise time reference of comparator 224a preset the flip-flop 26a at T2 to output a logic state “1”. The coincidence of a the fall time mark pulse from mark register 224 at T8 with the fall time reference of comparator 244a clears the flip-flop 26a to output a logic state “0”. Similarly, different words for channel 2 and channel can be generated. For Channel 1, the rise time is at the rise time of first mark pulse, the fall time at the rise time of the third mark pulse. For Channel 2, the rise time is at the rise time of the second mark pulse, fall time at the rise time of the third mark pulse. For Channel 3, the rise time is at the rise time of the fourth mark pulse, the fall time at the rise time of the fifth mark pulse. Note that in FIG. 3b, no rise time register and fall time register is needed, since mark timing pulses are directly supplied by the memory.

When the down counter 206 receives a signal from the memory 204 to produce a mark pulse, the memory sends out signal to specify the number of clock pulses the down counter 206 should count down to zero for the next mark pulse.

While the preferred embodiments of the invention have been described, it will be apparent to those skilled in the art that various modifications may be made in the embodiments without departing from the spirit of the present invention. Such modifications are all within the scope of this invention.

1. A digital word generator:
a memory;
an address counter for addressing said memory;
a rise time digital word stored in said memory, and outputted when a first logic state of a digital word is desired from said digital word generator;
a first digital comparator for comparing said rise time digital word with a reference rise time digital word;
a latch for latching the output logical state only when the stored rise time digital word coincides with the reference rise time digital word;
a fall time digital word stored in said memory, and outputted when a second logic state of a digital word is desired from said word generator;
a second digital comparator for comparing said fall time digital word with a reference fall time digital word and for clearing the latch to a second logic state, only when the fall time digital word coincides with the reference fall time digital word; and
a counter for counting the clock pulses fed to said memory and for resetting the address counter after a predetermined number of said clock pulses.

2. A digital word generator as described in claim 1, further comprising a first register to store the rise time digital word, and a second register to store the fall time digital word.

3. A digital word generator as described in claim 1, wherein said memory is a random access memory (RAM).

4. A digital word generator as described in claim 1, wherein said latch is a flip-flop.

5. A digital word generator as described in claim 1, wherein said counter is a down counter.

6. A digital word generator as described in claim 1, further comprising more than one first digital comparator, more than one second digital comparator, and more than one latch for generating multiple digital words, for generating more than one digital word in more than one channel.

7. A digital word generator as described in claim 6, wherein the memory supplies a number of mark pulses at mark times, which are fed to the rise time register and the fall time register,
each of said first comparator has a unique timing reference to compare with said mark times;
each of said second comparator has another unique timing reference to compare with said mark times
each of said flip-flop is preset when the rise time timing reference coincides with one of said mark times and the flip-flop is cleared when the fall time timing reference coincides with one of said mark times.

8. A digital word generator as described in claim 7, wherein said rise time register and fall time register are eliminated.
